(19) United States
(12) Patent Application Publication
(10) Pub. No.: US 2019/0305518 A1
(43) Pub. Date: Oct. 3, 2019

(54) VCSEL LASER DIODE HAVING A CARRIER CONFINEMENT LAYER AND METHOD OF FABRICATION OF THE SAME

(71) Applicant: Commissariat A L'Energie Atomique et aux Energies Alternatives, Paris (FR)

(72) Inventors: Nicolas OLIVIER, Grenoble Cedex (FR); Christophe JANY, Grenoble Cedex (FR)

(73) Assignee: Commissariat A L'Energie Atomique et aux Energies Alternatives, Paris (FR)

(21) Appl. No.: 16/364,241

(22) Filed: Mar. 26, 2019

(30) Foreign Application Priority Data
Mar. 29, 2018 (FR) 18 52737

(51) Int. Cl. H01S 5/183; H01S 5/343; H01S 5/042; H01S 5/02; H01S 5/022

(52) U.S. Cl. CPC H01S 5/18361; H01S 5/34313; H01S 5/0224; H01S 5/0425; H01S 5/0217; H01S 5/18322

(57) ABSTRACT

A laser diode of the VC SEL type includes, superimposed on top of a substrate, a bottom Bragg mirror, a region of one or more quantum wells, and a top Bragg mirror. A section of the bottom Bragg mirror has an area that is less than that of a section of the top Bragg mirror, the sections being defined in planes parallel to the plane of the substrate. The laser diode further includes a peripheral region, constituted by a confinement material, situated between the substrate and the top Bragg mirror, and surrounding at least the bottom Bragg mirror. The laser diode is devoid of any laterally-oxidized layer. Thanks to the specific geometrical configuration of the laser diode, the charge carriers are confined, during operation, to the center of the laser diode.

### TECHNICAL FIELD

The invention relates to the field of laser diodes, which are optoelectronic components based on semiconductor materials capable of emitting light. It more particularly relates to the field of vertical-cavity surface-emitting laser or VCSEL diodes.

### PRIOR ART

A VCSEL-type laser diode is constituted by a stack comprising, superimposed above a substrate, a region of one or more quantum wells and two Bragg mirrors. The two Bragg mirrors jointly form an optical cavity, inside which is situated the region of one or more quantum wells. During operation, a laser beam emerges from the optical cavity, oriented along an axis orthogonal to the substrate.

FIG. 1 shows a laser diode of the VCSEL-type according to the prior art, made of aluminium (Al), gallium (Ga) and arsenic (As). The laser diode 100 is shown by way of a sectional view in the plane (y0z) of an orthonormal coordinate system (0xyz). The plane (x0yy) extends parallel to the plane of a substrate 110.

The laser diode 100 comprises, superimposed above the substrate 110:
a buffer region 120, having a first doping type, n or p;
a bottom Bragg mirror 130 with high reflectivity at an emission wavelength of the laser diode 100;
a region of one or more quantum wells 140, capable of emitting photons in response to an excitation provided by an electric current;
a confinement layer 170, described hereafter;
a top Bragg mirror 150 with high reflectivity at an emission wavelength of the laser diode 100; and
a contact region 160 having a second doping type, p or n, the second doping type being opposite to the first dopant type.

FIG. 1 also shows:
a top metal electrode 1806, situated on a top side of the contact region 160, and open at the centre to allow for the passage of the laser beam emitted by the diode, during operation; and
a bottom metal electrode 180A.

An excitation in the region of one or more quantum wells 140 is obtained by injecting electric charge carriers, using an electric current flowing through the laser diode from top to bottom, between the top metal electrode 180B and the bottom metal electrode 180A.

In order to obtain the most directive laser emission possible, along the axis (Oz) orthogonal to the plane of the substrate 110, channelling of the injection of carriers towards the centre of the laser diode is known.

In the example shown in FIG. 1, the charge carriers are guided towards the centre of the laser diode by way of the confinement layer 170. This is a thin aluminium-enriched, laterally-oxidised AlGaAs based layer. The confinement layer 170 thus comprises a peripheral region with a high aluminium oxide content, surrounding a central, unoxidised region. The lateral oxidation is obtained by annealing in an oxygen-highly enriched environment. In operation, the peripheral region repels the carriers towards the central region and confines them in a central region of the laser diode 100.

This solution is described, for example, in an article by M. S. Alias & al., “Optimization of Electro-Optical Characteristics of GaAs-based Oxide Confinement VCSEL”, LASER PHYSICS, Vol. 20, No. 4, 2010, pp. 806-810.

However, this solution poses difficulties in terms of repeatability, in particular connected to controlling the thickness of the confinement layer, controlling the aluminium composition thereof, and controlling the lateral oxidation process. It is therefore difficult to produce series of laser diodes having constant electro-optical characteristics, both within the laser diode, but also from one laser diode to the next. These difficulties increase with the size of the substrate, when numerous diodes are produced together on the same substrate, by depositing layers over large surface areas and then etching trenches to isolate the diodes from one another.

Another known solution for confining the carriers to the centre of the laser diode consists of carrying out proton implantation in a peripheral region of the top Bragg mirror. In this case, the laser diode does not comprise the aluminium-enriched confinement layer, thus overcoming the aforementioned difficulties. However, the ion implantation process can damage the crystal lattice of the laser diode which is detrimental to the quality of the laser emission. Moreover, the implanted protons scatter, in the laser diode, in a pear-shaped volume. This solution is therefore ill-suited to small-scale laser diodes.

One purpose of the present invention is to propose a solution for confining charge carriers to the centre of a VCSEL-type laser diode, that does not suffer from the drawbacks of the prior art.

In particular, one purpose of the present invention is to propose a VCSEL-type laser diode in which a solution for confining charge carriers to the centre of the laser diode can be implemented using a method with high repeatability.

### DESCRIPTION OF THE INVENTION

This purpose is fulfilled using a laser diode comprising, superimposed above a substrate, along an axis orthogonal to the plane of said substrate:
a bottom Bragg mirror,
a region of one or more quantum wells, and
a top Bragg mirror,
   wherein the bottom Bragg mirror is situated between the substrate and the region of one or more quantum wells.

The laser diode according to the invention is thus a VCSEL-type laser diode.

According to the invention, a section of the bottom Bragg mirror has an area that is less than that of a section of the top Bragg mirror, said sections being defined in planes parallel to the plane of the substrate.

During operation, the confinement of the charge carriers to the centre of the laser diode is ensured, by construction, thanks to the reduced section of the bottom Bragg mirror. In other words, the invention proposes a spatial confinement of the charge carriers by way of a specific geometrical configuration of the laser diode.

As in the prior art, confinement allows a laser emission with high directivity to be obtained, oriented along an axis orthogonal to the plane of the substrate. The confinement solution proposed by the invention does not involve ion implantation or the lateral oxidation of a confinement layer. Confinement is obtained by a suitable dimensioning of the bottom Bragg mirror relative to the top Bragg mirror. This confinement solution can be implemented simply by etching layers to the desired dimensions, i.e. by a method with high repeatability. This high repeatability in particular allows for the homogenisation of the optical performance levels, in particular in terms of the optical aperture, of laser diodes jointly produced on the same substrate.

The invention further relax the constraints regarding the epitaxy of the layers forming the laser diode, by increasing the tolerances concerning the thickness and composition of each layer, compared to the prior art comprising a laterally-oxidised confinement layer. It in particular overcomes the restrictions concerning the epitaxy of an aluminium-enriched confinement layer.

In confinement solutions implementing ion implantation or the lateral oxidation of a confinement layer, a miniaturisation of the laser diode is limited by a minimum volume occupied by the ion implantation or by the oxidised material. The solution proposed by the invention overcomes these limits and thus provides access to laser diodes with smaller dimensions than those of the prior art. The laser diodes according to the invention can in particular be distributed in an array, distributed according to a reduced distribution pitch of less than or equal to 5 μm.

The carriers are confined as a result of the dimensions of the bottom Bragg mirror. By contrast, the top Bragg mirror can have a wide section, easing the production of a top electrode of the laser diode, situated on the side of the region of one or more quantum wells opposite the substrate.

Preferably, the laser beam emitted during operation by the laser diode emerges therefrom by passing through the top Bragg mirror. For this purpose, the bottom Bragg mirror has a reflectivity that is greater than that of the bottom Bragg mirror, at an emission wavelength of the laser diode. A top electrode of the laser diode is thus advantageously open at the centre to allow the laser beam to pass therethrough. The production of a top electrode that is open at the centre is made easier by the larger section of the top Bragg mirror, which is greater than that of the bottom Bragg mirror.

The laser diode according to the invention advantageously comprises:
a first cylindrical stack comprising at least the bottom Bragg mirror, and having a first section in a plane parallel to the plane of the substrate; and
a second cylindrical stack comprising at least the top Bragg mirror, and having a second section in a plane parallel to the plane of the substrate;
   wherein the region of one or more quantum wells belongs to the first or to the second stack, and wherein the area of the first section is less than the area of the second section.

The term “cylindrical” is used herein to refer to a right cylinder, the generator whereof is orthogonal to the plane of the substrate, however not necessarily to a right circular cylinder.

According to the invention, the laser diode of the invention comprises a so-called peripheral region, situated between the substrate and the top Bragg mirror, and surrounding the bottom Bragg mirror at least. The peripheral region in particular extends between the substrate and the second stack as defined hereinabove, while surrounding the first stack. The term “confinement material” can be understood to mean the one or more materials constituting the peripheral region, said region confining the charge carriers in the bottom Bragg mirror.

Said peripheral region can be constituted by at least one electrically insulating material or undoped semiconductor material, in direct physical contact with the side walls of the bottom Bragg mirror. Alternatively, said peripheral region can be constituted by at least one electrically conducting material, with a sleeve made of an electrically insulating material for separating it from the side walls of the bottom Bragg mirror. In any case, the side walls of the bottom Bragg mirror are in direct physical contact with a material preventing any lateral leaking of the charge carriers.

The invention further relates to a method for manufacturing a laser diode according to the invention, the method comprising:
a first etching step, in which a first series of layers is etched, said first series of layers at least comprising a first optically-reflective set of elementary layers, so as to form a first stack comprising at least the bottom Bragg mirror;
a second etching step, in which a second series of layers is etched, said second series of layers at least comprising a second optically-reflective set of elementary layers, so as to form a second stack comprising at least the top Bragg mirror; and
a step of laterally encapsulating the first stack, implemented after the first etching step;
   wherein a section of the first stack has an area that is less than that of a section of the second stack, and wherein the second etching step is implemented after the first etching step.

### BRIEF DESCRIPTION OF THE FIGURES

This invention will be better understood after reading the following description of example embodiments, given for purposes of illustration only and not intended to limit the scope of the invention, and with reference to the accompanying figures, wherein:

FIG. 1 diagrammatically shows a sectional view of a laser diode of the VCSEL type according to the prior art;

FIG. 2 diagrammatically shows a sectional view of a first embodiment of a laser diode of the VCSEL type according to the invention;

FIGS. 3 and 4 respectively show a sectional view of second and third embodiments of a laser diode of the VCSEL type according to the invention;

FIG. 5 diagrammatically shows a first embodiment of a method of manufacture according to the invention; and

FIGS. 6 and 7 respectively show second and third embodiments of a method according to the invention.

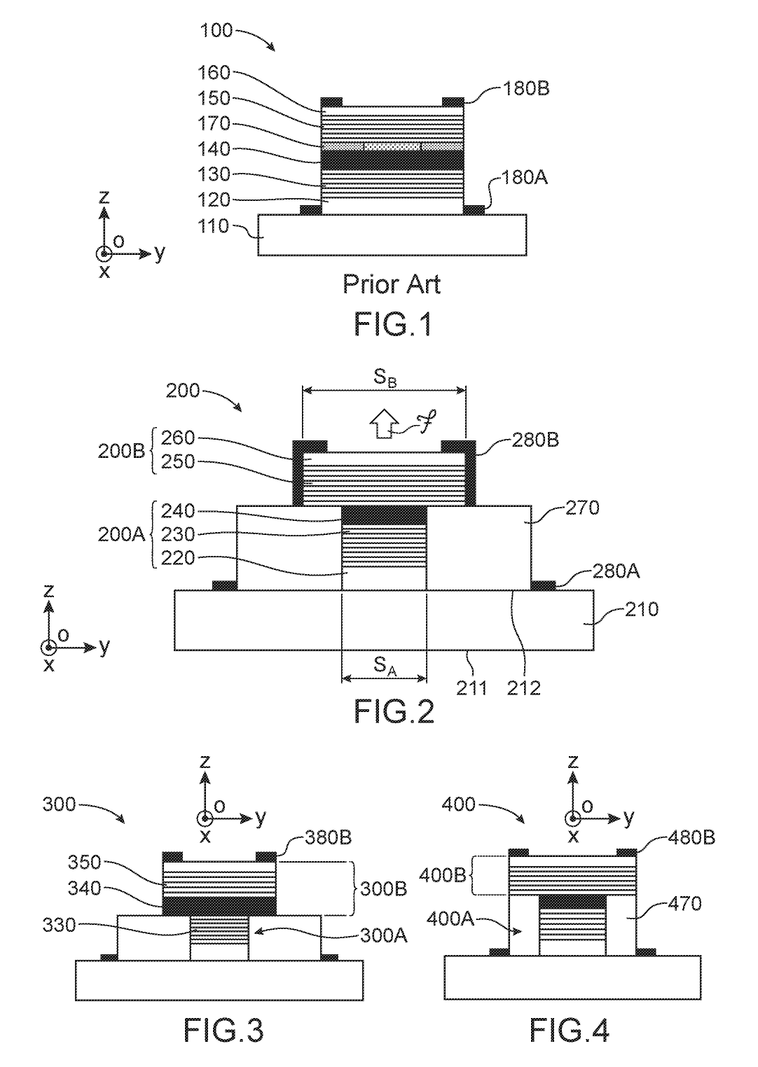

### DETAILED DESCRIPTION OF SPECIFIC EMBODIMENTS

FIG. 2 shows a first embodiment of a laser diode 200 according to the invention. The laser diode 200 is shown by way of a sectional view in the plane (y0z) of an orthonormal coordinate system (0xyz).

A substrate 210, also referred to as a host substrate, has a rectangular parallelepiped shape with a bottom side 211 and a top side 212, each of which extend in a plane parallel to the plane (x0y). The plane of the substrate is defined as being a plane parallel to said plane (x0y). The substrate 210 is, for example, made of gallium arsenide (GaAs).

The laser diode 200 comprises, superimposed in the specified order on top of the substrate 210, along an axis (0z) orthogonal to the plane of the substrate:
a buffer region 220 (optional), in this case constituted by a thin layer of doped GaAs, with a first n- or p-doping type;
a bottom Bragg mirror 230 with high reflectivity at an emission wavelength of the laser diode 200, in this case constituted by alternating layers of gallium arsenide (GaAs) and layers of aluminium gallium arsenide (AlGaAs);
a region of one or more quantum wells 240, in this case constituted by at least one quantum well formed by a stack of at least one layer of gallium arsenide (GaAs) and at least one layer of indium arsenide or of indium gallium arsenide (In(Ga)As);
a top Bragg mirror 250 with high reflectivity at an emission wavelength of the laser diode 200, also constituted by alternating layers of GaAs and layers of AlGaAs; and
a contact region 260 (optional), in this case constituted by a thin layer of doped gallium arsenide (GaAs), with a second p- or n-doping type, which is of type opposite to the first doping type.

The laser diode 200 does not comprise any local proton-enriched region produced by ion implantation, nor any laterally-oxidised confinement layer.

A quantum well in particular denotes a heterostructure made of a semiconductor material. The dimension of the heterostructure in one of the directions in space is equal to several tens of nanometres. The region of one or more quantum wells 240, or active region, allows for the generation of photons under the effect of electric excitation, at a wavelength that lies in the range 600 nm to 1,300 nm (depending on the composition, thickness and quantity of the quantum wells). During operation, the photons generated in the region of one or more quantum wells 240 are reflected by the bottom and top Bragg mirrors until the laser effect is obtained. The emission of light takes place along an axis orthogonal to the plane of the substrate 210.

The bottom Bragg mirror 230 has a reflectivity that is greater than that of the top Bragg mirror 250, at the emission wavelength of the region of one or more quantum wells 240. For example, a reflection rate of the bottom Bragg mirror 230 is greater than 99%, and a reflection rate of the top Bragg mirror 250 lies in the range 90% to 98%, at an emission wavelength of the region of one or more quantum wells 240. During operation, a laser beam Y emerges from the laser diode 200, on the side of the region of one or more quantum wells 240 opposite the substrate, by passing through the top Bragg mirror 250. The reflectivity of each of the Bragg mirrors is a function of the number of AlGaAs/GaAs bilayers. Thus, the bottom mirror will have a high number of bilayers (high reflectivity) and the top mirror will have fewer (low reflectivity), so that the photons can exit via the top.

The elements of the laser diode 200 listed hereinabove are distributed in two basic superimposed stacks:
a first stack 200A, in this case comprising the buffer region 220, the bottom Bragg mirror 230 and the region of one or more quantum wells 240; and
a second stack 200B, in this case comprising the top Bragg mirror 250 and the contact region 260.

The first stack 200A has the shape of a right cylinder, the generator whereof is parallel to (0z) and the section S_{A} whereof is parallel to the plane (x0y). The section S_{A} has a width that preferably lies in the range 6 μm to 8 μm, however that is not limited thereto. This is, by way of a non-limiting example, a disc having a diameter that lies in the range 6 μm to 8 μm or a square having a side that lies in the range 6 μm to 8 μm.

The second stack 200B has the shape of a right cylinder, the generator whereof is parallel to (0z) and the section S_{B} whereof is parallel to the plane (x0y).

According to the invention, the area of the section S_{A} is less than the area of the section S_{B}. The difference between the area of the section S_{B} and the area of the section S_{A} is, for example, greater than or equal to 10%, 25% or even 40% of the area of the section S_{B}.

In one specific case, each of the sections S_{A} and S_{B} have a disc shape, the diameters whereof are different. In another specific case, each of the sections S_{A} and S_{B} have a square shape, a side of each square having a different value.

A central axis of the first stack 200A, parallel to (0z), is aligned with a central axis of the second stack 200B, parallel to (0z). The first and second stacks 200A, 200B jointly form a structure having a T-shaped section in a plane parallel to the axis (0z).

The bottom Bragg mirror 230, belonging to the first stack 200A, thus has a section that is less than that of the top Bragg mirror 250, belonging to the second stack 200B. During operation, charge carriers are confined to the centre of the laser diode 200 thanks to the reduced section of the bottom Bragg mirror 230.

In this case, the laser diode 200 further comprises a so-called peripheral region 270 which extends between the substrate 210 and the second stack 200B, while surrounding the first stack 200A. It has the shape of a right cylinder, the generator whereof is parallel to (0z), and the section whereof is open in its center in order to allow the first stack 200A to pass therethrough. In this case, the peripheral region 270 projects laterally relative to the second stack 200B, in planes parallel to the plane (x0y).

The peripheral region 270 is constituted by a solid material such as a dielectric (for example SiN, SiO₂, SiOx, or a combination thereof), a polymer (for example benzocyclobutene), an undoped semi-conductor (for example a so-called group III-V semiconductor composed of one or more elements from column III and from column V of Mendeleev's periodic table), or even a metal oxide (for example Al₂O₃). It is in particular constituted by at least one material from the group of materials listed hereinabove. It is formed, for example, by a stack of layers, each of which is formed by one of the materials listed hereinabove.

Preferably, the peripheral region 270 is made of an undoped semiconductor or electrically insulating material, and extends in direct physical contact with the side walls of the first stack 200A.

Alternatively, the peripheral region 270 is made of an electrically conducting material (metal oxide) and is separated from the side walls of the first stack 200A by a sleeve made of an electrically insulating material (for example a dielectric such as SiN, SiO₂, SiOx or a combination thereof; a polymer, or benzocyclobutene).

In any case, the side walls of the bottom Bragg mirror are in direct physical contact with a material preventing any lateral leaking of the charge carriers.

The laser diode according to the invention thus has an architecture of the type “Semi Insulating Buried Heterostructure”, in this case buried in the peripheral region 270.

FIG. 2 also shows:
a top metal electrode 280B of the laser diode, open at the centre to allow the laser beam F to pass therethrough; and
a bottom metal electrode 280A.

In this case, the bottom metal electrode 280A extends over the substrate 210, while surrounding the peripheral region 270.

Depending on whether the substrate 210 is electrically conducting or electrically insulating, the bottom metal electrode 280A can extend:
on the side of the substrate 210 opposite the first stack 200A;
on the same side of the substrate 210 as the first stack 200A, while partially or fully surrounding the peripheral region 270; or
on the same side as the substrate 210 and while extending as far as beneath the first stack 200A.

In this case, the top metal electrode 280B extends both on a top side of the second stack 200B, on the side opposite the substrate 210, and on the side walls of said second stack 200B.

Preferably, at least half of the total surface area of the top metal electrode 280B extends over the side walls of the second stack 200B. If need be, the top metal electrode 280B can extend in full over the side walls of the second stack 200B.

This arrangement of the top metal electrode 280B, at least partially over the side walls of the second stack 200B, has numerous advantages:
the top Bragg mirror is laterally protected;
the total surface area of the top metal electrode is increased, which improves the injection of an exciting current into the laser diode;
a minimum section of the second stack 200B can be reduced, thus reducing the lateral dimensions of the laser diode;
restrictions with respect to dimensioning and positioning of the top metal electrode can be relaxed, while guaranteeing sufficient passage to allow the laser beam emitted by the laser diode to pass.

The production of the top metal electrode 280B at least partially on the side walls of the second stack 200B is made easier in this case by the fact that the peripheral region 270 laterally projects relative to the first stack 200A. The peripheral region 270 thus forms a border to delimit the span of the top metal electrode 280B, and ensure that it does not protrude as far as the region of one or more quantum wells.

In the embodiment shown in FIG. 2, the top metal electrode 280B extends over all side walls of the second stack 200B. Alternatively, it can extend over only a portion thereof, for example over at least 20% of the surface area thereof.

According to another alternative embodiment, not shown, the top metal electrode extends only over one top side of the second stack 200B. This alternative embodiment is more particularly suited to a large-scale laser diode.

According to the invention, the bottom Bragg mirror 230 defines the smaller guide aperture for the charge carriers in the laser diode. In other words, the bottom Bragg mirror 30 alone serves to confine the charge carriers in the laser diode. This smaller aperture is located on the side of the region of one or more quantum wells opposite an emission surface of the laser diode.

Moreover, the bottom Bragg mirror 230 defines the smaller guide aperture for the optical mode in the laser diode. Thus, the bottom Bragg mirror 30 alone serves to confine the charge carriers and the optical mode in the laser diode.

Preferably, the laser diode is devoid of any guiding layer separate from the bottom Bragg mirror, producing a lateral confinement of the charge carriers and/or of the optical mode.

FIG. 3 shows a second embodiment of a laser diode 300, which is only described herein as regards the differences thereof relative to the embodiment in FIG. 2.

In this case, the region of one or more quantum wells 340 belongs to the second stack 300B, and not to the first stack 300A. In other words, the region of one or more quantum wells 340 has the same section as the top Bragg mirror 350, and not the same section as the bottom Bragg mirror 330.

In this embodiment, but in a non-limiting manner, the top metal electrode 380B extends only over one top side of the second stack 300B.

FIG. 4 shows a third embodiment of a laser diode 400, which is only described herein as regards the differences thereof relative to the embodiment in FIG. 2.

In this case, the peripheral region 470 does not laterally project relative to the second stack 400B. The peripheral region 470 and the first stack 400A jointly form a bottom right cylinder, the section whereof is the same as that of a top right cylinder defining the shape of the second stack 400B. The generator of the top right cylinder is aligned with that of the bottom right cylinder.

In this embodiment, but in a non-limiting manner, the top metal electrode 480B extends only over one top side of the second stack 400B.

The paragraphs below describe example methods for the manufacture of a laser diode according to the invention. By way of a illustration, but in a non-limiting manner, the case of the manufacture of a laser diode as shown in FIG. 2 is described.

Each of these embodiments share the fact that they comprise:
a first etching step, in which a first series of layers is etched, said first series of layers at least comprising a first optically-reflective set of elementary layers, so as to form the first stack comprising at least the bottom Bragg mirror; and
a second etching step, in which a second series of layers is etched, said second series of layers at least comprising a second optically-reflective set of elementary layers, so as to form the second stack comprising at least the top Bragg mirror.

A set of so-called quantum well(s) elementary layers is etched during the first or during the second etching step, in order to form the region of one or more quantum wells.

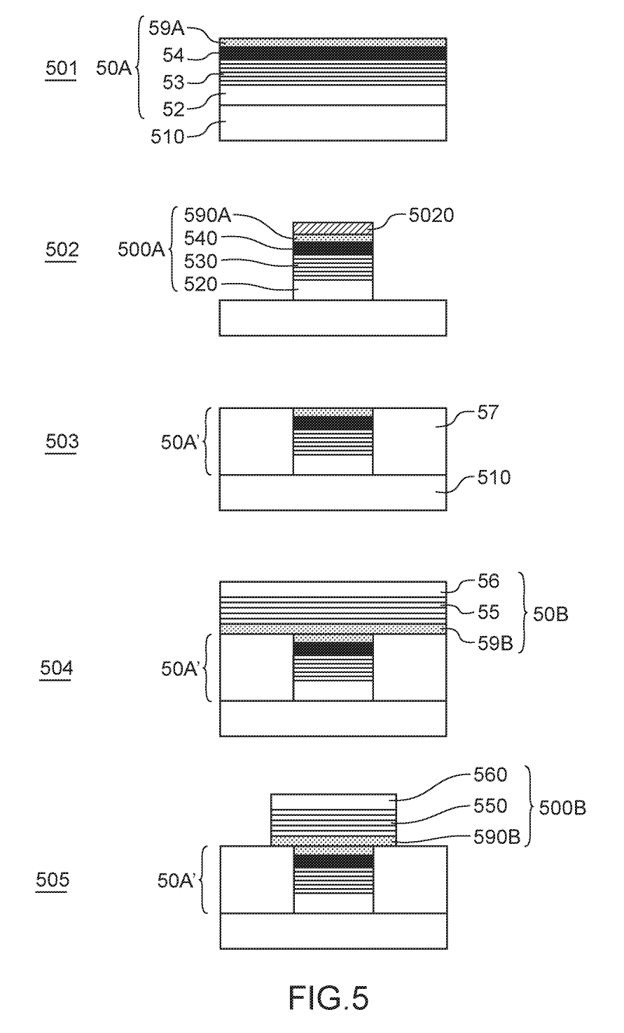

The method in FIG. 5 comprises the following steps, which are implemented in the specified order:

### Step 501:

A first epitaxy on a first substrate 510 in order to form a first series of layers 50A comprising:
a buffer layer 52, of the same kind as the buffer region described with reference to FIG. 2;
a first set 53 of elementary layers, optically-reflective, of the same kind as the bottom Bragg mirror described with reference to FIG. 2;
a set 54 of so-called quantum well(s) elementary layers, of the same kind as the region of one or more quantum wells described with reference to FIG. 2; and
a first delay layer 59A, in this case constituted by a thin layer of doped GaAs (in this case of a doping type opposite to that of the buffer layer 52), situated on the side opposite to the first substrate 510.

In this case, the first substrate 510 corresponds to the substrate described with reference to FIG. 2, also referred to as the host substrate.

### Step 502:

A first etching, during which the first series of layers 50A is etched throughout the thickness thereof, as far as the first substrate 510, so as to form a first stack 500A. The first stack 500A comprises the buffer region 520, the bottom Bragg mirror 530, and the region of one or more quantum wells 540 of a laser diode according to the invention, as well as a first delay region 590 formed in the first delay layer 59A.

The first etching is, for example, a plasma-enhanced etching of the Reactive-Ion Etching (RIE) type or of the Inductively Coupled Plasma (ICP) type or of the RIE/ICP type. Alternatively, the etching is of the ion beam etching type (Ion Beam Etching (IBE) or Chemically Assisted Ion Beam Etching (CAIBE), or Reactive Ion Beam Etching (RIBE)). The first etching uses a first mask 5020 to protect the areas not to be etched. The first mask 5020 can be a dielectric (SiN, SiOx, etc.) or a metal, or a photosensitive resin, etc.

### Step 503:

Epitaxial regrowth on the first substrate 510 and around the first stack 500A in order to grow a lateral encapsulating layer 57 of the same kind as the peripheral region described with reference to FIG. 2. Preferably, the lateral encapsulating layer 57 is constituted from an undoped semiconductor, in particular a group III-V material whith lattice-match compatible with the substrate 510.

The epitaxial regrowth is then followed by a removal of the first mask 5020 by dry etching or wet etching.

The step 503 forms a so-called lateral encapsulation step of the first stack 500A. The purpose thereof is to planarise the topography of a structure covering the first substrate 510. A top side of the first stack 500A, on the side opposite the first substrate 510, remains free, not covered by the material of the lateral encapsulating layer 57.

At the end of step 503, the first substrate 510 is covered by a first planar structure 50A′ comprising the first stack 500A and the lateral encapsulating layer 57.

### Step 504:

New epitaxy in order to form, on the first structure 50A′, a second series of layers 50B, in this case comprising:
a second delay layer 59B, in this case constituted from a thin layer of doped GaAs (of the same doping type as the first delay layer 59A);
a second set 55 of elementary layers, optically-reflective, of the same kind as the top Bragg mirror described with reference to FIG. 2; and
a contact layer 56, of the same kind as the contact region described with reference to FIG. 2, in direct physical contact with the first delay region 590.

### Step 505:

A second etching, during which the second series of layers 50B is etched throughout the thickness thereof, as far as the first structure 50A′, so as to form a second stack 500B, in this case comprising a second delay region 590B formed in the second delay layer 59B, the top Bragg mirror 550 and the contact region 560.

The second etching can implement the same etching techniques as the first etching. It can be carried out in a vacuum, using chlorine gases of the type BCl₃, Cl₂, SiCl₄ or carbonated gaseous mixtures of the type CH₄/H₂. The addition of a neutral gas can improve the etching (Ar, N₂, etc.). A chemical etching technique can also be used, for example using hydrogen bromide. The second etching uses a second mask, not shown, to protect the areas not to be etched. The second mask can be a dielectric (SiN, SiOx, etc.) or a metal, or a photosensitive material.

After the second etching, or jointly therewith, trenches are etched in the lateral encapsulating layer 57 in order to delimit the peripheral region of the diode, in the lateral encapsulating layer 57. This etching can be a RIE and/or ICP plasma etching method using fluorinated gases (CHF₃, SF₃, CF₄, etc.) alone or mixed with inert gases, or an ion plasma etching method (IBE, RIBE, CAIBE), etc. It uses an etching mask which can be removed, or kept after having been etched at the centre thereof.

Top and bottom electrodes are then produced, as shown in FIGS. 2 to 4. The material of the electrodes is deposited by physical vapour deposition (PVD). The geometry of each electrode can be defined by etching (lift off, or electron beam-induced etching, for example). The top electrode can extend in full or in part over side walls of the second stack, as described with reference to FIG. 2.

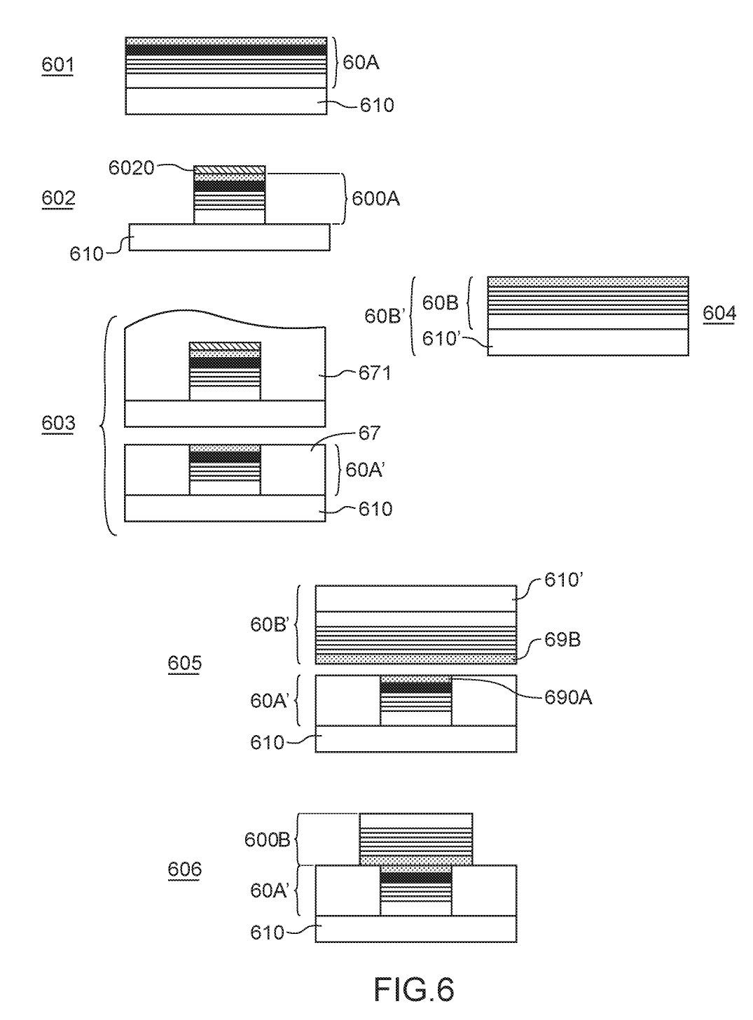

FIG. 6 shows a second embodiment, which comprises the following steps, implemented in the specified order:

### Step 601:

A first epitaxy in order to form a first series of layers 60A on a first substrate 610 as described with reference to FIG. 5 as regards step 501. In this case, the first substrate 610 corresponds to the substrate described with reference to FIG. 2, also referred to as the host substrate.

### Step 602:

A first etching, identical to the etching 502 in FIG. 5, during which the first series of layers 60A is etched throughout the thickness thereof, as far as the first substrate 610, so as to form a first stack 600A. The first etching uses a first mask 6020 to protect the areas not to be etched.

### Step 603:

A lateral encapsulation of the first stack 600A comprising the bottom Bragg mirror 630. At the end of step 603, the first substrate 610 is covered by a first planar structure 60A′, as described with reference to FIG. 5 as regards step 503.

In this case, lateral encapsulation is implemented by the deposition of an encapsulating layer 671 above the first substrate 610 and by planarisation.

The encapsulating layer 671 surrounds and covers the assembly formed by the first stack 600A and the first mask 6020. It is constituted, for example, from a dielectric material (SiN, SiO₂, SiOx, or a combination thereof, etc.) or from a polymer material (benzocyclobutene for example), or from a metal oxide (Al₂O₃ for example). If the encapsulating layer 671 is made of a metal oxide, a sleeve made of an electrically insulating material, as described with reference to FIG. 2, is produced before the deposition of the encapsulating layer 671.

Planarisation is carried out by chemical-mechanical polishing. It further allows the first etching mask 6020 to be removed. After planarisation, that which remains of the encapsulating layer 671 forms a layer referred to as a lateral encapsulating layer 67.

### Step 604:

A second epitaxy, on a second substrate 610′, to form a second series of layers 60B as described with reference to FIG. 5 as regards step 504. The second substrate 610′ and the second series of layers 60B jointly form a second structure 60B′.

The step 604 can be implemented in full or in part in parallel with steps 601 to 603, which increases the speed of manufacture of a laser diode according to the invention.

### Step 605:

Placement of the second structure 60B′ on the first structure 60A′ by direct bonding. During bonding, a first delay region 690A of the first structure, situated on the side opposite to the first substrate 610, and a second delay layer 69B of the second structure, situated on the side opposite to the second substrate 610′, are in direct physical contact with one another.

The second substrate 610′ is then removed, for example by chemical etching, mechanical polishing, chemical-mechanical polishing, and/or epitaxial lift off etching.

### Step 606:

A second etching, during which the second series of layers 60B is etched throughout the thickness thereof, as far as the first structure 60A′, so as to form a second stack 600B, as described with reference to step 505 in FIG. 5. This second etching is carried out after the removal of the second substrate 610′.

As described with reference to FIG. 5, a step of etching trenches in the lateral encapsulating layer 67 is implemented at the same time as or after the second etching.

In this case, the etching of trenches can be a RIE and/or ICP plasma etching method as described hereinabove, or a wet or dry etching method (etching of a dielectric by wet etching using hydrofluoric acid or using a buffered etching oxide solution, etching of a polymer by wet etching using trichloroethylene, or etching of a metal by dry or wet etching).

Top and bottom electrodes are then produced, as described hereinabove.

The methods in FIGS. 5 and 6 can be combined. For example, in the method in FIG. 5, step 504 can be replaced by steps 604 and 605 of the method in FIG. 6.

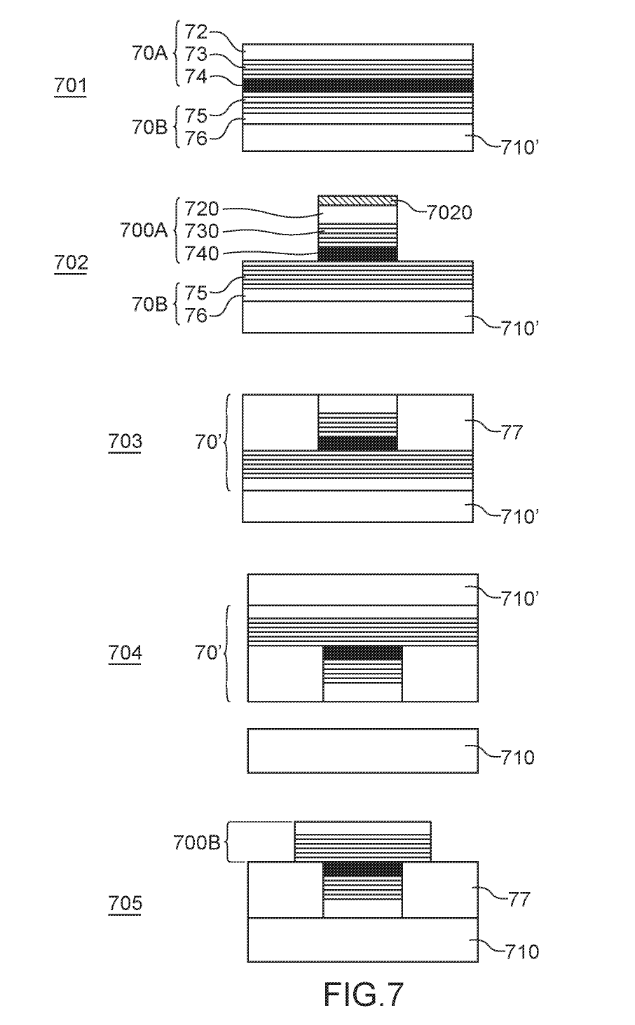

In the methods in FIGS. 5 and 6, the laser diode is formed by two separate epitaxies, each of which provides one or more electrical and/or optical functions. A third epitaxy can be carried out to produce the lateral encapsulation of the first stack. FIG. 7 shows a third embodiment implementing a single epitaxy. This method comprises the following steps, which are implemented in the specified order:

### Step 701:

An epitaxy, on a first substrate 710′, of a stack of layers, in this case comprising, in the order specified, starting from the first substrate 710′:
a contact layer 76, of the same kind as the contact region described with reference to FIG. 2;
a second set 75 of elementary layers, optically-reflective, of the same kind as the top Bragg mirror described with reference to FIG. 2; and
a set 74 of so-called quantum well(s) elementary layers 74, of the same kind as the region of one or more quantum wells described with reference to FIG. 2;
a second set 73 of elementary layers, optically-reflective, of the same kind as the bottom Bragg mirror described with reference to FIG. 2; and
a buffer layer 72, of the same kind as the buffer region described with reference to FIG. 2.

The first substrate 710′ corresponds to an intermediate substrate, separate from the substrate on which the diode will ultimately rest.

### Step 702:

A first etching, during which the stack is etched over only one part of the thickness thereof. In this case, a first series of layers 70A is etched, said first series of layers being constituted by the quantum well(s) set 74, the first set 73 of elementary layers, and the buffer layer 72. In this way, a first stack 700A is formed, in this case comprising the buffer region 720, the bottom Bragg mirror 730 and the region of one or more quantum wells 740 of a laser diode according to the invention. The first stack 700A in this case extends over a second series of layers 70B, in this case constituted by the second set 75 of elementary layers and the contact layer 76.

The first etching uses one of the etching techniques listed with reference to FIG. 5, step 502. It uses a first mask 7020 to protect the areas not to be etched.

### Step 703:

A lateral encapsulation of the first stack 700A, as described with reference to FIG. 6, step 603, or with reference to FIG. 5, step 503.

At the end of this step, a so-called upside-down planar structure 70′ is obtained on the first substrate 710, in which structure one side of the first stack 700A is flush with the surface of the lateral encapsulating layer 77, on the side opposite to the first substrate 710′.

### Step 704:

Placement, on a second substrate 710, of the assembly formed by the first substrate 710′ and the upside-down structure 70′, and removal of the first substrate 710′. During placement, the assembly formed by the first substrate 710′ and the upside-down structure 70′ is turned over, such that the first substrate 710′ is situated on the side opposite to the second substrate 710.

In this case, the second substrate 710 corresponds to the substrate described with reference to FIG. 2, also referred to as the host substrate, on which the diode will ultimately rest.

### Step 705:

A second etching, during which the upside down structure 70′ turned over on the second substrate 710 is etched over only a part of the thickness thereof. This second etching is carried out after the removal of the first substrate 710′. In this case, the second series of layers 70B constituted by the contact layer 76 and the second set 75 of elementary layers is etched. The second etching is stopped at the interface with the lateral encapsulating layer 77. It produces a second stack 700B in the second series of layers 70B. It implements techniques such as those described with reference to step 505 in FIG. 5 or step 606 in FIG. 6.

As described with reference to FIG. 5, a step of etching trenches in the lateral encapsulating layer 77 is implemented at the same time as or after the second etching.

Top and bottom electrodes are then produced, as described hereinabove.

The placement step is implemented before the second etching and before the production of the electrodes, such that it only involves entirely planar structures and does not require any specific alignment. After the placement, no sacrificial layer extends between the second substrate 710 and the upside down structure 70′. The laser diodes are intended to remain on the second substrate 170. In particular, they are not placed on a third substrate by a “pick and place” type method.

The invention is not limited to the example methods and devices described hereinabove. For example:
the buffer region can be n-doped and the contact region can be p-doped, or vice-versa;
the substrate of the laser diode can be a so-called group III-V substrate (comprised of one or more elements from the column III and from the column V of Mendeleev's periodic table), or a silicon substrate (insulated silicon layer or silicon layer belonging to a stack of the silicon-on-insulator type, etc.) or any other suitable substrate. The silicon used can be treated to provide the usual electrical functions used in CMO-type microelectronics.
the bottom and top Bragg mirrors and the region of one or more quantum wells can be formed from a material based on GaN (gallium nitride) (VCSEL GaN) or any other suitable semiconductor material. GaAs and AlGaAs-based materials are, however, preferred.

Preferably, a plurality of laser diodes is jointly produced on the same substrate or wafer. The etching of trenches to delimit the peripheral region of each diode can be used to isolate the diodes from one another.

The invention further covers a so-called “RC-LED” light emitting device (RC-LED stands for Resonant Cavity—Light Emitting Diode), which differs from a VCSEL-type laser diode in that it is devoid of the top Bragg mirror. In such a case, the second stack as described herein is devoid of the top Bragg mirror. It preferably comprises an n- or p-doped contact region, as described herein. Advantageously, it further comprises an active photon-emitting region, such as the multi-quantum wells region described herein.

The invention is in particular applicable to the field of telecommunications by optical fibres, and to the field of light detection and ranging (three-dimensional imaging, LIDAR system mounted on a motor vehicle, etc.).

1. A laser diode comprising, superimposed on top of a substrate along an axis orthogonal to the plane of said substrate:
a bottom Bragg mirror,
a region of one or more quantum wells, and
a top Bragg mirror,
wherein the bottom Bragg mirror is situated between the substrate and the region of one or more quantum wells, wherein
a section of the bottom Bragg mirror has an area that is less than that of a section of the top Bragg mirror, said sections being defined in planes parallel to the plane of the substrate; and
the laser diode comprises a peripheral region, constituted by a confinement material; situated between the substrate and the top Bragg mirror, and surrounding at least the bottom Bragg mirror; and
said laser diode is devoid of any laterally-oxidised layer.

2. The laser diode according to claim 1, further comprising at least one top electrode, which extends in full or in part over side walls of the top Bragg mirror.

3. The laser diode according to claim 1, wherein the side walls of the bottom Bragg mirror are in direct physical contact with at least one undoped semiconductor or electrically insulating material.

4. The laser diode according to claim 1, wherein the laser diode is constituted by gallium arsenide-based materials.

5. A method for manufacturing a laser diode according to claim 1, comprising:
a first etching step, in which a first series of layers is etched, said first series of layers at least comprising a first set of elementary layers which is optically-reflective, so as to form a first stack comprising at least the bottom Bragg mirror;
a second etching step, in which a second series of layers is etched, said second series of layers at least comprising a second set of elementary layers, which is optically-reflective, so as to form a second stack comprising at least the top Bragg mirror; and
a step of laterally encapsulating the first stack, implemented after the first etching step;
wherein a section of the first stack has an area that is less than that of a section of the second stack, and wherein the second etching step is implemented after the first etching step.

6. The method according to claim 5, further comprising:
a first epitaxy on a first substrate in order to form the first series of layers;
the first etching step in order to form the first stack comprising at least the bottom Bragg mirror;
the lateral encapsulation step at the end whereof a first planar structure is obtained on the first substrate;
a second epitaxy on a second substrate that is separate from the first substrate, in order to form the second series of layers, the second series of layers and the second substrate jointly forming a second structure;
a placement of the second structure on the first structure, followed by a removal of the second substrate; and
the second etching step, implemented after the placement step, in order to form the second stack comprising at least the top Bragg mirror.

7. The method according to claim 6, wherein the first epitaxy and the second epitaxy are at least partially implemented simultaneously.

8. The method according to claim 5, further comprising:
a first epitaxy on a first substrate in order to form the first series of layers;
the first etching step in order to form the first stack comprising at least the bottom Bragg mirror;
the lateral encapsulation step at the end whereof a first planar structure is obtained on the first substrate;
a new epitaxy on the first structure in order to form the second series of layers; and
the second etching step, implemented after the new epitaxy, in order to form the second stack comprising at least the top Bragg mirror.

9. The method according to claim 5, further comprising:
an epitaxy on a first substrate in order to form a series of layers comprising the second series of layers and the first series of layers;
the first etching step in order to form the first stack comprising at least the bottom Bragg mirror;
the lateral encapsulation step at the end whereof an upside-down planar structure is obtained on the first substrate;
a placement, on a second substrate, of the assembly formed by the first substrate and the upside-down structure, followed by a removal of the first substrate; and
the second etching step, implemented after the placement step, in order to form the second stack comprising at least the top Bragg mirror.

10. The method according to claim 5, wherein the step of laterally encapsulating the first stack comprises sub-steps of depositing an encapsulating layer and planarization.

11. The method according to claim 5, wherein the step of laterally encapsulating the first stack comprises a step of material growth.

12. The method according to claim 5, further comprising a step of producing a top electrode, carried out after the second etching step, and such that said top electrode extends in full or in part over side walls of the first stack.
